(19) United States
(12) Patent Application Publication
(10) Pub. No.: US 2018/0090861 A1
(43) Pub. Date: Mar. 29, 2018

(54) Electrical Connections And their Use in Wearables and Other Applications

(71) Applicant: E I DU PONT DE NEMOURS AND COMPANY, Wilmington, DE (US)

(72) Inventors: Mark Allan Lamontia, Landenberg, PA (US); Joseph James Duffy, Newark, DE (US)

(21) Appl. No.: 15/695,413

(22) Filed: Sep. 5, 2017

Related U.S. Application Data
(60) Provisional application No. 62/400,859, filed on Sep. 28, 2016.

(51) Int. Cl. H01R 12/59; H01R 4/28; H05K 1/02; A41D 1/00

(52) U.S. Cl. CPC H01R 12/592; H01R 4/28; H01R 4/60; A41D 1/005; H05K 1/0213

(57) ABSTRACT

This invention is directed to electrical circuits containing electrical connections of an electrical conductor in the form of a wire and a printed electrical conductor, methods of forming such connections and wearable garments and other articles with electrical circuits containing such electrical connections. One or more stitches with non-conductive thread each encompass the portion of the two conductors that are in contact.

### FIELD OF THE INVENTION

This invention is directed to electrical circuits containing electrical connections of an electrical conductor in the form of a wire and a printed electrical conductor, methods of forming such connections and wearable garments and other articles with electrical circuits containing such electrical connections. The printed circuit may be on a sewable substrate or a solid substrate.

### BACKGROUND OF THE INVENTION

There is increasing interest in incorporating electrical circuits in wearable garments to monitor physiological aspects of the wearer. Examples of such measurements include heart rate, electrocardiography, electromyography, surface and core body temperature and bodily fluids. Electrical circuits may also be incorporated into non-wearable articles such as vehicle seats. These electrical circuits contain electrical contacts between electrical conductors. There is a need for methods of forming good electrical contacts that may be used in the construction of a functional circuit and that can maintain conductivity as the garment or article is stretched and exposed to multiple wash and dry cycles.

### SUMMARY OF THE INVENTION

This invention provides an electrical circuit comprising:
a) a first electrical conductor printed on a sewable substrate;
b) a second electrical conductor in the form of a wire, a portion of which is in contact with a portion of the electrical conductor printed on the sewable substrate; and
c) one or more stitches with non-conductive thread, wherein each stitch is sewn through the sewable substrate with each stitch encompassing the portions of the two electrical conductors that are in contact, thereby providing the compression necessary to form an electrical connection.

This invention also provides an electrical circuit comprising:
a) a first electrical conductor printed on a solid substrate containing pre-arranged pairs of holes;
b) a second electrical conductor in the form of a wire, a portion of which is in contact with a portion of the electrical conductor printed on the solid substrate, wherein the portion of the wire is placed between the pairs of holes; and
c) one or more stitches with non-conductive thread, wherein each stitch is sewn through a pair of holes with each stitch encompassing the portions of the two electrical conductors that are in contact, thereby providing the compression necessary to form an electrical connection.

In addition, this invention provides a method for forming an electrical connection between two electrical conductors, comprising:
a) providing a first electrical conductor printed on a sewable substrate;
b) providing a second electrical conductor in the form of a wire;
c) contacting a portion of the wire with a portion of the electrical conductor printed on the sewable substrate, and
d) sewing one or more stitches with non-conductive thread through the sewable substrate with each stitch encompassing the portions of the two electrical conductors that are in contact, thereby providing the compression necessary to form an electrical connection.

This invention further provides a wearable garment with an electrical circuit, the electrical circuit comprising:
a) a first electrical conductor printed on a sewable substrate;
b) a second electrical conductor in the form of a wire, a portion of which is in contact with a portion of the electrical conductor printed on the sewable substrate; and
c) one or more stitches with non-conductive thread sewn through the sewable substrate with each stitch encompassing the portions of the two electrical conductors that are in contact, thereby providing the compression necessary to form an electrical connection.

This invention also provides an article with an electrical circuit, the electrical circuit comprising:
a) a first electrical conductor printed on a sewable substrate;
b) a second electrical conductor in the form of a wire, a portion of which is in contact with a portion of the electrical conductor printed on the sewable substrate; and
c) one or more stitches with non-conductive thread sewn through the sewable substrate with each stitch encompassing the portions of the two electrical conductors that are in contact, thereby providing the compression necessary to form an electrical connection.

### BRIEF DESCRIPTION OF THE FIGURES

FIG. 1 illustrates an electrical connection between an electrical conductor printed on a sewable substrate and a solid wire wherein the stitches encompass the entire portion of the electrical conductor printed on the sewable substrate that is in contact with the portion of the wire and the portion of the wire itself.

FIG. 2 illustrates an electrical connection between an electrical conductor printed on a sewable substrate and a solid wire wherein the stitches encompass only a part of the portion of the electrical conductor printed on the sewable substrate and all of the portion of the wire.

FIG. 3 illustrates an electrical connection between an electrical conductor printed on a sewable substrate and a solid wire wherein a section of the portion at the end of the wire makes an angle θ with respect to the main portion of the wire.

FIG. 4 illustrates an electrical connection between an electrical conductor printed on a sewable substrate and a solid wire wherein a section of the portion at the end of the wire is in the shape of a loop.

FIG. 5 illustrates an electrical connection between an electrical conductor printed on a sewable substrate and a braided wire.

### DETAILED DESCRIPTION OF THE INVENTION

The invention relates to electrical connections between a wire and a printed electrical conductor. In one embodiment the printed electrical conductor is on a sewable substrate. In another embodiment the printed electrical conductor is on a solid substrate. If the solid substrate is sufficiently thin, it can be pierced by the sewing needle and so can be treated as a sewable substrate.

Portions of the two conductors in contact are encompassed by one or more stitches with non-conductive thread to provide the compression needed to form an electrical connection. Typically, the portion of the wire in contact with the portion of the printed electrical conductor is the portion at the end of wire. However, the portion of the wire in contact with the portion of the printed conductor may be in an area away from the end of the wire. If the wire has insulation, the insulation is removed for the portion of the wire making the electrical connection with the printed conductor.

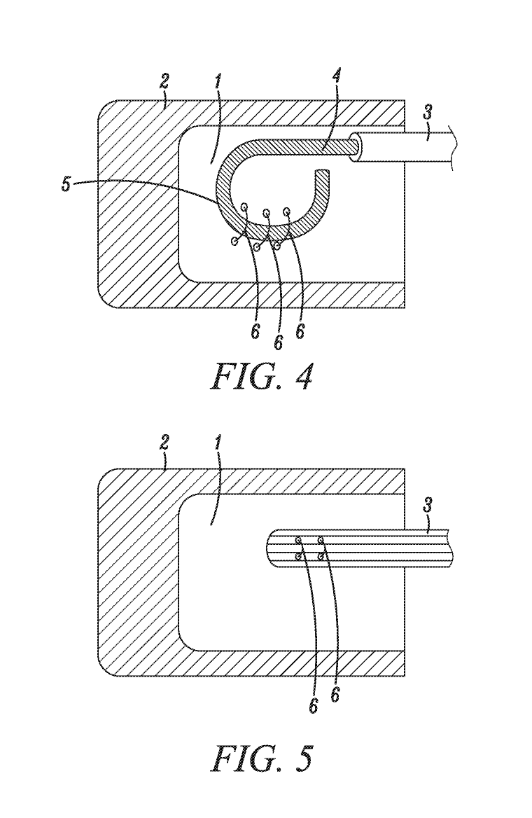

When the wire is a solid wire, the wire is more firmly held in the connection when a section of the portion at the end of the wire is not collinear with the remainder of the wire and the one or more stitches encompass a part of the section that is not colinear. The section may make an angle θ with respect to the main portion of the wire as shown in FIG. 3. The section may be in the shape of the letter u, of a loop, or of a curve or some other shape to prohibit the wire being pulled from under the stitches, an Example of which is shown in FIG. 4. The end of the wire may be attached to an electrical terminal and the electrical terminal is in contact with a portion of the electrical conductor printed on the sewable substrate, with each of the one or more stitches encompassing the portion of the electrical conductor printed on the sewable substrate and the electrical terminal.

As used herein, “wire” refers to a linear conductive material such as a solid metal wire, braided wire, stranded wire, a bar, a rod, a terminal at the end of a wire, a carbon fiber, a calrod or any other solid conductor.

As used herein, “printed conductor” refers to a conductor that has been screen printed or printed in any manner or otherwise affixed or transferred to the substrate.

As used herein, “multiplicity” refers to three or more.

The printed conductor is deposited on a substrate that may be directly used as a wearable garment or an article or that can be applied to a fabric that may be used as a wearable garment or an article. Either side of the substrate may be applied to the fabric of the wearable garment or article, i.e., the side of the substrate with the conductor can be adjacent to the fabric or the other side of the substrate may be adjacent to the fabric. One substrate is a thermoplastic polyurethane (TPU), such as Bemis ST-604 available from Bemis Associates, Inc., Shirley, Mass. Another possible substrate is a thermoplastic polyester, such as Hytrel® available from the DuPont Co., Wilmington, Del. The substrate may also be a sheet of a composite material made up of a combination of plastic sheet with a permeable coating deposited thereupon. A thermoplastic polyurethane substrate, such as Bemis ST-604, adheres to polyurethane or polyvinyl chloride coated fabrics.

In another embodiment the conductor composition may be applied directly to a stretchable permeable fabric. One such non-woven fabric is one constructed from Evolon® available from Fruedenberg Evolon, Colmar, France. Another permeable substrate that may be used for this type of application is a woven polyester coated with polyamide, e.g., Cetus® OS5000U available from Dynic Corp, Kyoto, Japan.

As indicated previously, portions of the two conductors in contact are encompassed by one or more stitches with non-conductive thread to provide the compression needed to form an electrical connection.

As used herein, “encompass” refers to embodiments wherein the one or more stitches surround the entire portion of the electrical conductor printed on the substrate and in contact with the wire and the wire itself as well as embodiments wherein only a part of the electrical conductor printed on the substrate and/or the wire is surrounded by one or more stitches.

A multiplicity of stitches results in a firmer and longer lasting connection. When a multiplicity of stitches is used, the stitches, may be a series of individual stitches, zig-zag stitches, or any other arrangement that provides the compression needed.

The printed electrical conductor may also be printed on a solid substrate. In this embodiment, the solid substrate contains pairs of prearranged holes. There is printed conductor between the pairs of holes and the portion of the wire in contact with the printed conductor is placed between the pairs of holes. One or more stitches with non-conductive thread is sewn through a pair of holes with each stitch encompassing the portions of the two conductors that are in contact, thereby providing the compression necessary to form an electrical connection.

Embodiments of some of the electrical connections will be discussed with reference to the Figures.

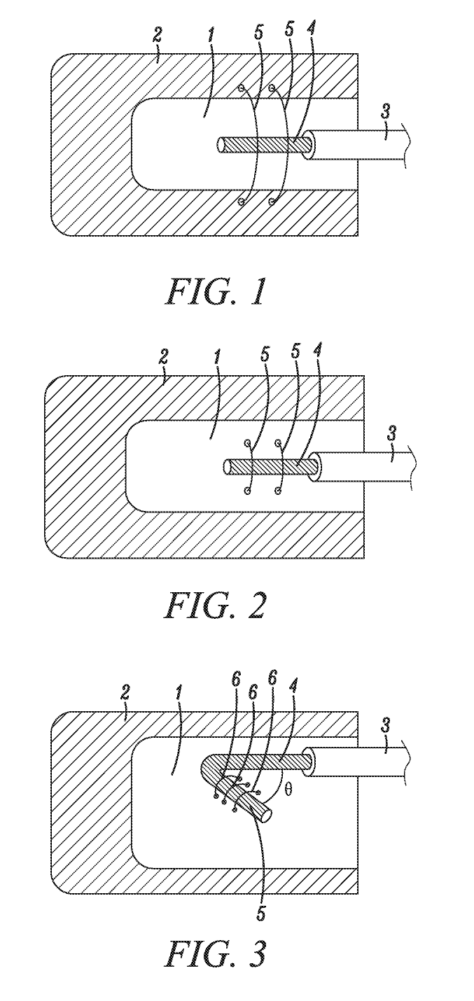

FIG. 1 illustrates an electrical connection between an electrical conductor printed on a sewable substrate and a solid wire wherein the stitches encompass the entire portion of the electrical conductor printed on the sewable substrate that is in contact with the portion of the wire and all of the portion of the wire. The electrical conductor 1 is printed on the sewable substrate 2. The wire 3 is shown with insulation. The end portion 4 of wire 3 has been stripped of the insulation and is in contact with electrical conductor 1. Two stitches 5 are shown surrounding the entire portion of the electrical conductor 1 and all of wire portion 4.

FIG. 2 illustrates an electrical connection between an electrical conductor printed on a sewable substrate and a solid wire wherein the stitches encompass only part of the electrical conductor printed on the sewable substrate and all of the portion of the wire. The electrical conductor 1 is printed on the sewable substrate 2. The wire 3 is shown with insulation. The end portion 4 of wire 3 has been stripped of the insulation and is in contact with electrical conductor 1. Two stitches 5 are sewn through electrical conductor 1 and surround only part of the electrical conductor 1 and all of wire portion 4.

FIG. 3 illustrates an electrical connection between an electrical conductor printed on a sewable substrate and a solid wire wherein a section of the portion at the end of the wire makes an angle θ with respect to the main portion of the wire. The electrical conductor 1 is printed on the sewable substrate 2. The wire 3 is shown with insulation. The end portion 4 of wire 3 has been stripped of the insulation and a section 5 of this portion 4 has been bent to form an angle θ with the main part of the wire 3. The angle θ is typically between 0 and 90 degrees. The section 5 is in contact with electrical conductor 1. Three stitches 6 are sewn through electrical conductor 1 and surround only part of the electrical conductor 1. The stitches 6 also surround all of the section 5 of the wire. This is one of the embodiments in which a section 5 of the portion 4 at the end of the wire is not collinear with the main part of the wire 3 and the wire is more firmly held by the stitches 6 surrounding the section 5. The wire would be even more firmly held by additional one or more stitches surrounding end portion 4.

FIG. 4 illustrates an electrical connection between an electrical conductor printed on a sewable substrate and a solid wire wherein a section of the portion at the end of the wire is in the shape of a loop. The electrical conductor 1 is printed on the sewable substrate 2. The wire 3 is shown with insulation. The end portion 4 of wire 3 has been stripped of the insulation and a section 5 of this portion 4 has been bent to form a loop. The section 5 is in contact with electrical conductor 1. Three stitches 6 are sewn through electrical conductor 1 and surround only part of the electrical conductor 1. The stitches 6 also surround the section 5 of the wire. This is another of the embodiments in which a section 5 of the portion 4 at the end of the wire is not collinear with the main part of the wire 3 and the wire is more firmly held by the stitches 6 surrounding the section 5. The wire would be even more firmly held by additional one or more stitches surrounding end portion 4.

If a stranded wire is used the stitches may encompass all the strands or the thread may pass between the strands and encompass only some of the strands. Alternatively, the strands at the end of the wire may be separated and each strand bent or curved and placed in contact with the section of the printed conductor and encompassed by one or more stitches in the same manner shown for a solid wire in FIGS. 3 and 4.

FIG. 5 illustrates an electrical connection between an electrical conductor printed on a sewable substrate and a braided wire. The electrical conductor 1 is printed on the sewable substrate 2. The braided wire 3 is in contact with electrical conductor 1. Two stitches 4 are sewn through electrical conductor 1 and through braided wire 3 and surround only part of the electrical conductor 1 and part of the braided wire 3.

### EXAMPLES

### Example 1

Sewn wire connections to a braided wire were constructed with screen printed conductors on thermoplastic polyurethane (TPU) that was hot pressed to a knit fabric. The printed conductors were about ¾ inch wide. They were composed of 2 silver/polymeric layers covered by 2 carbon layers. The braided wire used as the other conductor was commercially available flattened tubular construction of nickel plated copper wire. A multiplicity of stiches was used to encompass the printed conductor and the braided wire. The stitches were sewn through the braided wire as illustrated in FIG. 5. Resistance along an unmodified length of printed conductor was measured to be between 2 and 4 ohms at an electrical separation of 2 inches. Several stitch types were investigated both with the braided wire parallel to the printed conductor and perpendicular to the printed conductor. Stitch styles used were buttonhole, honeycomb, straight with close spacing, and running zig-zag. In all cases electrical resistance was measured to be between 1.75 and 3.5 ohms.

### Example 2

A sewn wire connection to a solid wire was constructed with a screen-printed conductor on thermoplastic polyurethane (TPU) that was hot pressed to a knit fabric. The printed conductor was about ¾ inch wide. They were composed of 2 silver/polymeric layers covered by 2 carbon layers. A solid copper wire was bent into a somewhat circular loop with an inside diameter of approximately ¾ inch as illustrated in FIG. 4. The wire loop was sewn to the printed conductor/TPU/knit fabric assembly using a button hole type stitch at three locations with a multiplicity of stitches at each location. Resistance was measured to be about 5.9 ohms with 2 inch center-to-center stitch spacing.

What is claimed is:

1. An electrical circuit comprising:
a) a first electrical conductor printed on a sewable substrate;
b) a second electrical conductor in the form of a wire, a portion of which is in contact with a portion of the electrical conductor printed on the sewable substrate; and
c) one or more stitches with non-conductive thread, wherein each stitch is sewn through the sewable substrate with each stitch encompassing the portions of the two electrical conductors that are in contact, thereby providing the compression necessary to form an electrical connection.

2. The electrical circuit of claim 1, wherein the portion of the wire in contact with the portion of the printed electrical conductor is the portion at the end of the wire.

3. The electrical circuit of claim 2, wherein the wire is a solid wire and a section of the portion at the end of the wire is not collinear with the remainder of the wire and wherein the one or more stitches encompass a part of the section.

4. The electrical circuit of claim 3, wherein at the section is at an angle θ with respect to the remainder of the wire and wherein the one or more stitches encompass a part of the section, wherein the angle θ is between 0 and 90 degrees.

5. The electrical circuit of claim 3, wherein the section is in the shape of a loop.

6. The electrical circuit of claim 3, wherein the section is in the shape of the letter u.

7. The electrical circuit of claim 2, wherein the wire is a braided wire and the one or more stitches pass through the braided wire.

8. The electrical circuit of claim 2, wherein the wire is a stranded wire and the individual strands in the portion at the end of the wire are each in the shape of a loop and wherein one or more stitches encompass a part of each loop.

9. The electrical circuit of claim 1, wherein the end of the wire is attached to an electrical terminal and the electrical terminal is in contact with a portion of the electrical conductor printed on the sewable substrate, with each of the one or more stitches encompassing the portion of the electrical conductor printed on the sewable substrate and the electrical terminal.

10. The electrical circuit of claim 1, wherein there is a multiplicity of stitches.

11. An electrical circuit comprising:
a) a first electrical conductor printed on a solid substrate containing pre-arranged pairs of holes, wherein there is printed conductor between the pairs of holes;
b) a second electrical conductor in the form of a wire, a portion of which is in contact with a portion of the electrical conductor printed on the solid substrate, wherein the portion of the wire is placed between the pairs of holes; and
c) one or more stitches with non-conductive thread, wherein each stitch is sewn through a pair of holes with each stitch encompassing the portions of the two electrical conductors that are in contact, thereby providing the compression necessary to form an electrical connection.

12. The electrical circuit of claim 11, wherein there is a multiplicity of stitches.

13. An article with an electrical circuit, the electrical circuit comprising:
a) a first electrical conductor printed on a sewable substrate;
b) a second electrical conductor in the form of a wire, a portion of which is in contact with a portion of the electrical conductor printed on the sewable substrate; and
c) one or more stitches with non-conductive thread, wherein each stitch is sewn through the sewable substrate with each stitch encompassing the portions of the two electrical conductors that are in contact, thereby providing the compression necessary to form an electrical connection.

14. The article of claim 13, wherein the portion of the wire in contact with the portion of the printed electrical conductor is the portion at the end of the wire.

15. The article of claim 14, wherein the wire is a solid wire and a section of the portion at the end of the wire is not collinear with the remainder of the wire and wherein the one or more stitches encompass a part of the section.

16. The article as of claim 13, wherein there is a multiplicity of stitches.

17. The article as of claim 13, wherein the article is a wearable garment.

18. The article of claim 17, wherein the portion of the wire in contact with the portion of the printed electrical conductor is the portion at the end of the wire.

19. The article of claim 18, wherein the wire is a solid wire and a section of the portion at the end of the wire is not collinear with the remainder of the wire and wherein the one or more stitches encompass a part of the section.

20. The article of claim 17, wherein there is a multiplicity of stitches.
